(19) United States
(12) Patent Application Publication
(10) Pub. No.: US 2013/0175640 A1
(43) Pub. Date: Jul. 11, 2013

(54) STRESS ENHANCED MOS TRANSISTOR AND METHODS FOR FABRICATION

(71) Applicants: Ralf Illgen, Dresden (DE); Stefan Flachowsky, Dresden (DE)

(72) Inventors: Ralf Illgen, Dresden (DE); Stefan Flachowsky, Dresden (DE)

(73) Assignee: GLOBALFOUNDRIES Inc., Grand Cayman (KY)

(21) Appl. No.: 13/345,432

(22) Filed: Jan. 6, 2012

(51) Int. Cl. H01L 21/336; H01L 29/78

(52) U.S. Cl. 257/402; 438/299; 257/E29.255; 257/E21.409

(57) ABSTRACT

A stress enhanced MOS transistor and methods for its fabrication are provided. In one embodiment the transistor includes a channel region at a surface of a semiconductor substrate. The method includes etching first recesses into the semiconductor substrate adjacent the channel region to define adjacent regions in the semiconductor substrate between the first recesses and the channel region. A first layer of SiGe is epitaxially grown in the first recesses. The method includes etching second recesses through the first layer of SiGe and into the adjacent regions of the semiconductor substrate. Further, a second layer of SiGe is epitaxially grown in the second recesses.

### TECHNICAL FIELD

The present disclosure generally relates to MOS transistors and to methods for their fabrication, and more particularly relates to stress enhanced MOS transistors and to methods for fabricating such transistors with embedded material adjacent the transistor channel.

### BACKGROUND

The majority of present day integrated circuits (ICs) are implemented by using a plurality of interconnected field effect transistors (FETs), which are also called metal oxide semiconductor field effect transistors (MOSFETs), or simply MOS transistors. A MOS transistor includes a gate electrode as a control electrode and spaced apart source and drain electrodes between which a current can flow. A control voltage applied to the gate electrode controls the flow of current through a channel between the source and drain electrodes.

The complexity of ICs and the number of devices incorporated in ICs are continually increasing. As the number of devices in an IC increases, the size of individual devices decreases. Device size in an IC is usually noted by the minimum feature size, that is, the minimum line width or the minimum spacing that is allowed by the circuit design rules. As the semiconductor industry moves to smaller minimum feature sizes, the performance of individual devices degrades as the result of scaling. As new generations of integrated circuits and the transistors that are used to implement those integrated circuits are designed, technologists must rely heavily on non-conventional elements to boost device performance.

The performance of a MOS transistor, as measured by its current carrying capability, is proportional to the mobility of the majority carrier in the transistor channel. It is known that applying a longitudinal stress to the channel of a MOS transistor can increase the mobility; a compressive longitudinal stress enhances the mobility of majority carrier holes and a tensile longitudinal stress enhances the mobility of majority carrier electrons. It is further known to create a longitudinal compressive stress to enhance the mobility of holes in P-channel MOS (PMOS) transistors by embedding silicon germanium (eSiGe) adjacent the transistor channel. To fabricate such a device, a recess is etched into the silicon substrate in the source and drain areas of the transistor and the recess is refilled by using epitaxial growth of the SiGe. While the use of eSiGe is well known, improved performance from eSiGe is desired.

Accordingly, it is desirable to optimize methods for fabricating stress enhanced MOS transistors. In addition, it is desirable to provide an optimized stress enhanced MOS transistor that avoids the problems attendant with conventional transistor fabrication. Furthermore, other desirable features and characteristics will become apparent from the subsequent detailed description and the appended claims, taken in conjunction with the accompanying drawings and the foregoing technical field and background.

### BRIEF SUMMARY

A method is provided for fabricating a stress enhanced MOS transistor. In accordance with one embodiment, the stress enhanced MOS transistor has a channel region at a surface of a semiconductor substrate. The method includes etching first recesses into the semiconductor substrate adjacent the channel region to define adjacent regions in the semiconductor substrate between the first recesses and the channel region. A first layer of SiGe is epitaxially grown in the first recesses. The method includes etching second recesses through the first layer of SiGe and into the adjacent regions of the semiconductor substrate. Then, a second layer of SiGe is epitaxially grown in the second recesses.

In accordance with another embodiment, a method is provided for fabricating a stress enhanced MOS device with a channel region at a surface of a semiconductor substrate beneath a gate electrode. In the method, a first recess is etched into the semiconductor substrate adjacent the channel region. Further, a first layer of SiGe is epitaxially grown in the first recess. The method includes etching a second recess through the first layer of SiGe and into the semiconductor substrate beneath the gate electrode. A second layer of SiGe is epitaxially grown in the second recess.

A stress enhanced MOS transistor having enhanced majority carrier hole mobility is provided. The stress enhanced MOS transistor includes a semiconductor substrate having a surface, a gate electrode formed on the surface, and a channel region at the surface beneath the gate electrode. Further, the stress enhanced MOS transistor includes a region of SiGe embedded in the semiconductor substrate adjacent to the channel region and extending beneath the gate electrode.

### BRIEF DESCRIPTION OF THE DRAWINGS

The stress enhanced MOS device and method of fabrication will hereinafter be described in conjunction with the following drawing figures, wherein like numerals denote like elements, and wherein

FIGS. 1-8 illustrate, in cross section, a stress enhanced MOS transistor and method steps for its fabrication in accordance with various embodiments herein.

### DETAILED DESCRIPTION

The following detailed description is merely exemplary in nature and is not intended to limit the stress enhanced MOS device, or the fabrication methods, applications or uses of the stress enhanced MOS device. Furthermore, there is no intention to be bound by any expressed or implied theory presented in the preceding technical field, background or brief summary, or in the following detailed description.

Monocrystalline silicon, the most common semiconductor material used in the semiconductor industry for the fabrication of semiconductor devices and integrated circuits is characterized by a lattice constant, a dimension of the silicon crystal. By substituting atoms other than silicon in a crystal lattice, the size of the resulting crystal and the lattice constant can be changed. If a larger substitutional atom such as a germanium atom is added to the silicon lattice, the lattice constant increases and the increase in lattice constant is proportional to the concentration of the substitutional atom. Similarly, if a smaller substitutional atom such as a carbon atom is added to the silicon lattice, the lattice constant decreases. Locally adding a large substitutional atom to a host silicon lattice creates a compressive stress on the host lattice and adding a small substitutional atom to a host silicon lattice creates a tensile stress on the host lattice.

It is known that increasing the germanium content of embedded SiGe increases the stress that can be applied to the channel of a PMOS transistor and thereby increases the mobility of majority carrier holes in the transistor. Herein, it is further contemplated that moving the embedded SiGe closer to the channel of a PMOS transistor, i.e., reducing the distance between the embedded SiGe and the channel, further increases the mobility of majority carrier holes in the transistor.

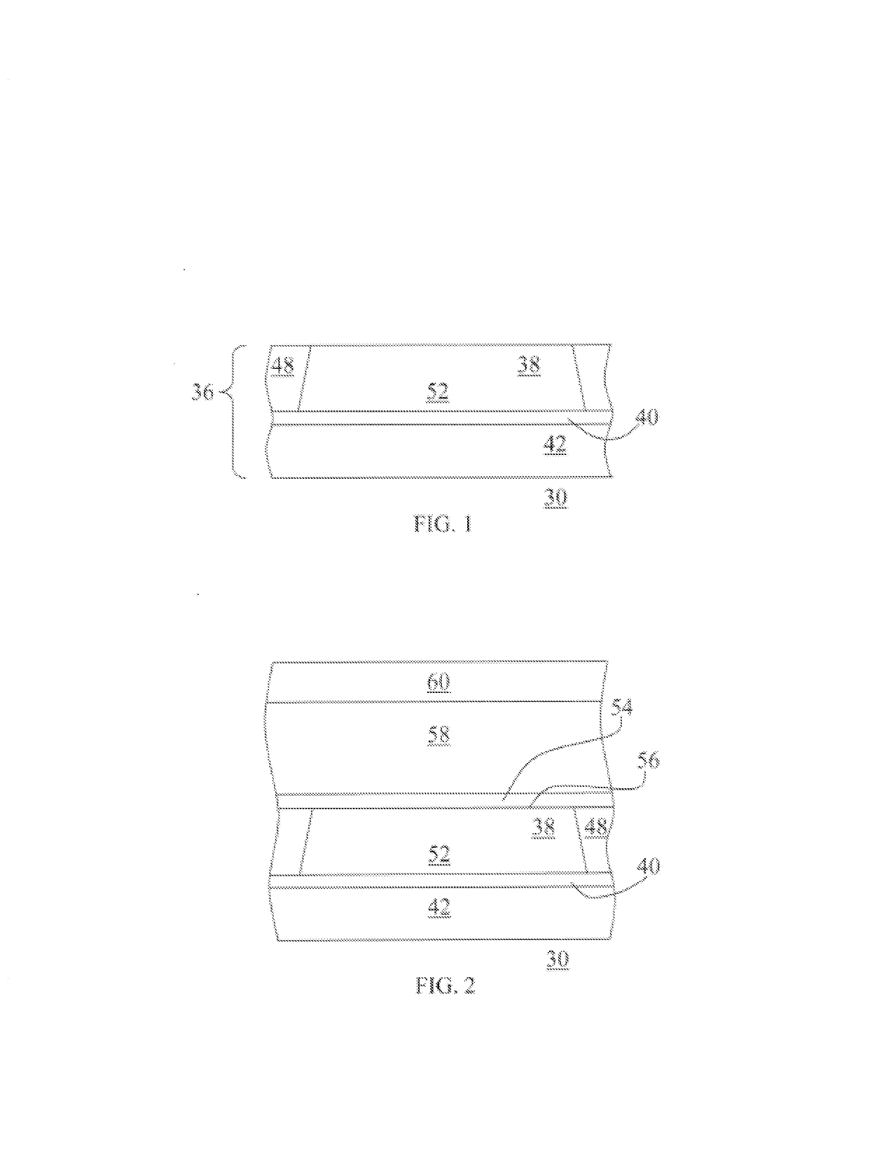

In accordance with the various embodiments herein, a MOS transistor and methods for fabricating such a device are provided with a reduced distance between the channel and the embedded SiGe in the region adjacent the channel to optimize the channel stress and mobility gain. FIGS. 1-6 illustrate, in cross section, a stressed MOS device 30 and method steps for fabricating such a MOS device in accordance with various embodiments herein. In the shown embodiment, a stressed MOS device 30 is illustrated by a single P-channel MOS (PMOS) transistor. An integrated circuit formed from stressed MOS devices such as device 30 can include a large number of such transistors, and may also include unstressed PMOS transistors and stressed and unstressed N-channel MOS (NMOS) transistors as well.

Various steps in the manufacture of MOS transistors are well known and so, in the interest of brevity, many conventional steps will only be mentioned briefly herein or will be omitted entirely without providing the well known process details. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

As illustrated in FIG. 1, the manufacture of a stressed MOS transistor 30 in accordance with an embodiment herein begins with providing a semiconductor substrate 36 in and on which such transistors are fabricated. The initial steps in the fabrication of MOS transistor 30 are conventional and will not be described in detail. The semiconductor substrate is preferably a silicon substrate having a (100) surface crystal orientation wherein the term “silicon substrate” and “silicon layer” are used herein to encompass the relatively pure monocrystalline silicon materials typically used in the semiconductor industry as well as silicon admixed with other elements such as germanium, carbon, and the like. Semiconductor substrate 36 will hereinafter be referred to for convenience but without limitation as a silicon substrate although those of skill in the semiconductor art will appreciate that other semiconductor materials could be used. Silicon substrate 36 may be a bulk silicon wafer (not illustrated), but preferably is a thin monocrystalline layer of silicon 38 on an insulating layer 40 (commonly know as silicon-on-insulator or SOI) that, in turn, is supported by a carrier wafer 42. Thin silicon layer 38 typically has a thickness of less than about 200 nanometers (nm) depending on the circuit function being implemented, and in certain applications preferably has a thickness less than about 90 nm. The thin silicon layer preferably has a resistivity of at least about 5 to about 40 Ohm centimeter. The silicon can be impurity doped either N-type or P-type, but is preferably doped P-type. Dielectric insulating layer 40, typically silicon dioxide, preferably has a thickness of about 50 to about 200 nm.

Isolation regions 48 are formed and may extend through monocrystalline silicon layer 38 to dielectric insulating layer 40. The isolation regions 48 are preferably formed by well known shallow trench isolation (STI) techniques in which trenches are etched into monocrystalline silicon layer 38, the trenches are filled with a dielectric material such as deposited silicon dioxide, and the excess silicon dioxide is removed by chemical mechanical planarization (CMP). STI regions 48 provide electrical isolation, as needed, between various devices of the circuit that are to be formed in monocrystalline silicon layer 38. Either before or preferably after fabrication of the STI regions, selected portions of silicon layer 38 can be impurity doped, for example by ion implantation. For example, an N-type well 52 can be impurity doped N-type for the fabrication of PMOS transistor 30.

A layer of gate insulator 54 is formed on surface 56 of silicon layer 38 as illustrated in FIG. 2. The gate insulator may be thermally grown silicon dioxide formed by heating the silicon substrate in an oxidizing ambient, or may be a deposited insulator such as a silicon oxide, silicon nitride, a high dielectric constant insulator such as HfₓSi_{y}O_{z}, or the like. Deposited insulators can be deposited in known manner, for example, by chemical vapor deposition (CVD), low pressure chemical vapor deposition (LPCVD), semi-atmospheric chemical vapor deposition (SACVD), or plasma enhanced chemical vapor deposition (PECVD). Gate insulator 54 is here illustrated as a thermally grown silicon dioxide layer. The gate insulator material is typically about 1 to about 10 nm in thickness and preferably is grown to, or has, a thickness of about 1 to about 2 nm. In accordance with one embodiment herein a layer of gate electrode forming material 58, preferably polycrystalline silicon, is deposited onto the layer of gate insulator. Other electrically conductive gate electrode forming materials such as metals and metal silicides may also be deposited. The gate electrode forming material will hereinafter be referred to as polycrystalline silicon although those of skill in the art will recognize that other materials can also be employed. If the gate electrode material is polycrystalline silicon, that material is typically deposited to a thickness of about 50 to about 200 nm and preferably to a thickness of about 100 nm by LPCVD by the hydrogen reduction of silane. The layer of polycrystalline silicon is preferably deposited as undoped polycrystalline silicon and is subsequently impurity doped by ion implantation. A layer of hard mask material 60 such as a layer of silicon nitride is deposited over the polycrystalline silicon gate electrode forming material. The layer of masking material, if silicon nitride, can be deposited, for example, by PECVD to a thickness of about 30 to about 50 nm from the reaction of dichlorosilane and ammonia. Those of skill in the art will understand that other dielectric materials other than silicon nitride can be deposited as the hard mask material.

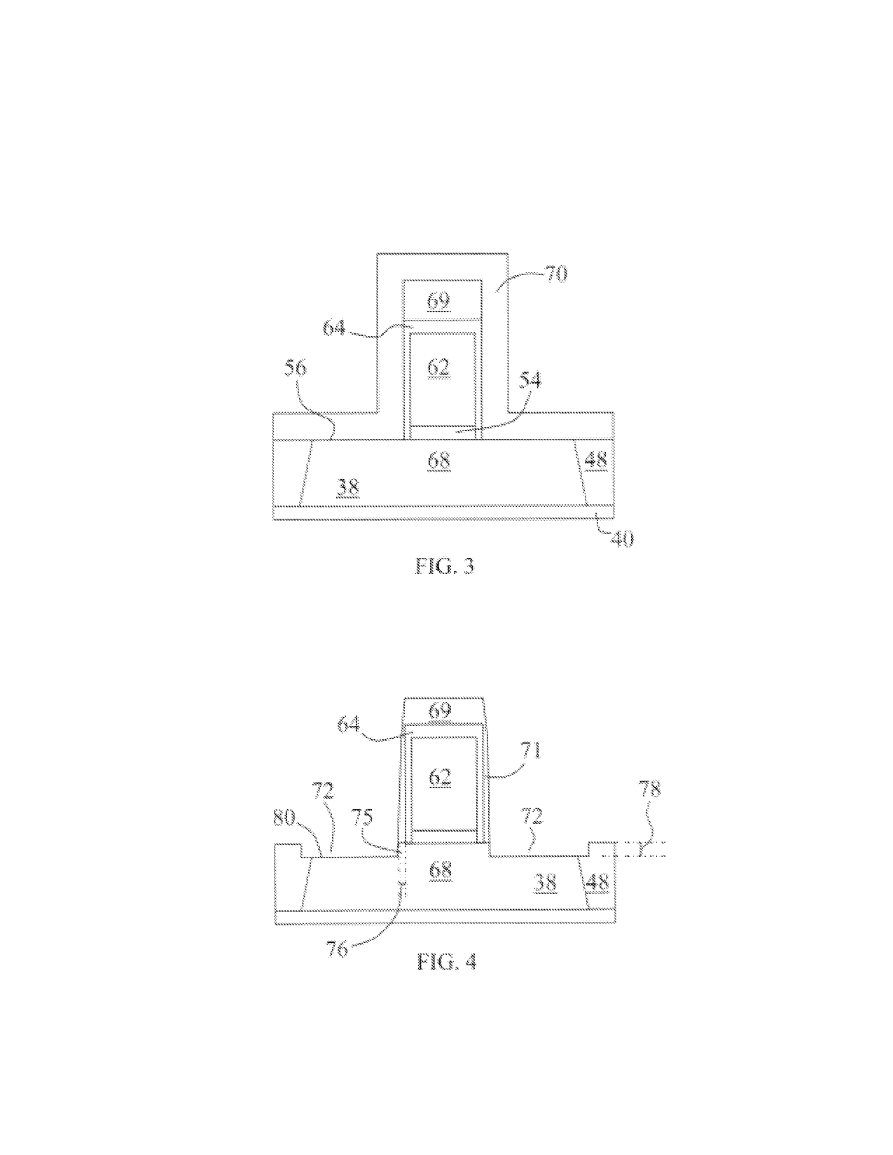

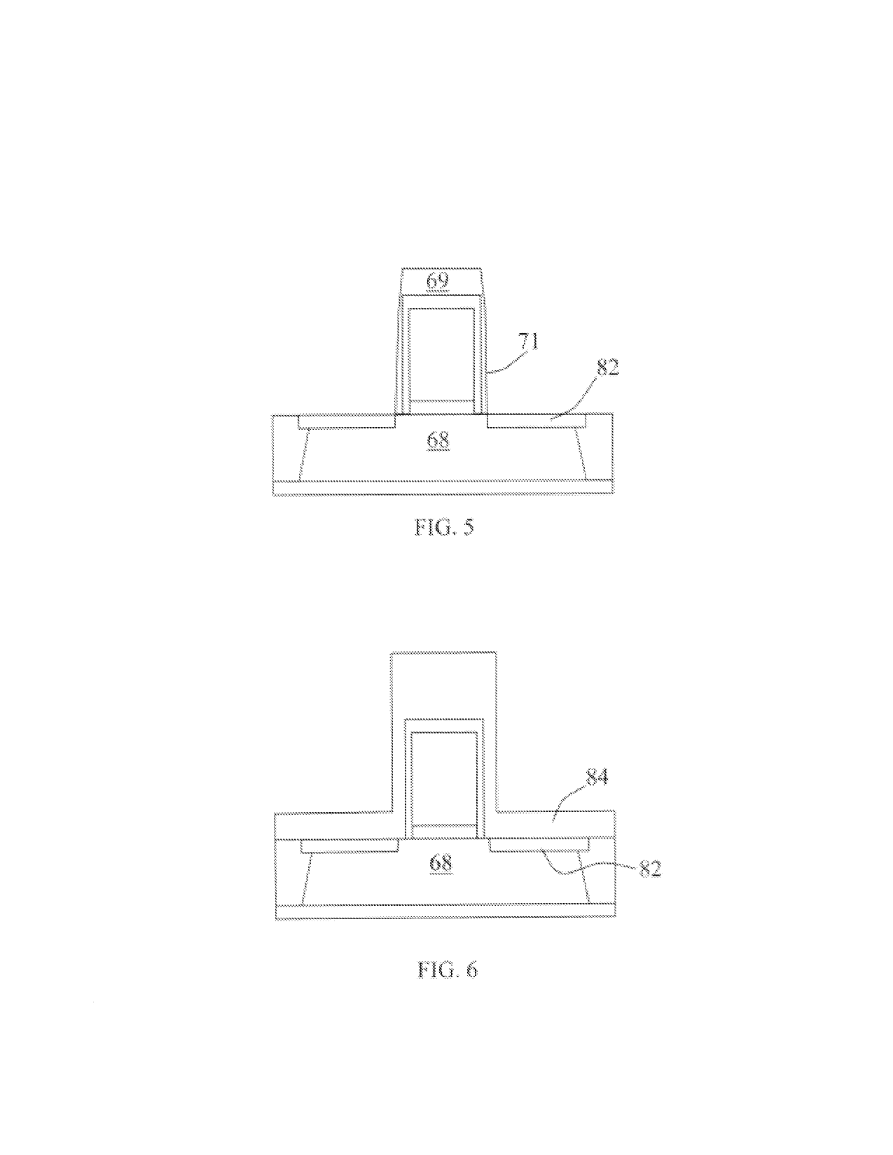

As illustrated in FIG. 3, hard mask material 60, gate electrode forming material 58, and gate insulator 54 are photolithographically patterned and etched to form a gate electrode 62 on the surface 56 of silicon layer 38 as is well known. Etching in the desired pattern can be accomplished by, for example, plasma etching in a Cl or HBr/O₂ chemistry and/or in a CHF₃, CF₄, or SF₆ chemistry. Thereafter the hard mask material 60 is removed, and a silicon oxide liner 64 is thermally grown over the top and along the sidewalls of gate electrode 62. Thin oxide layer 64 provides a liner to separate the polycrystalline silicon gate electrode from subsequently deposited spacer forming materials. The silicon oxide liner 64 can have a thickness, for example, of about 2 to about 3 nm. The formation of gate electrode 62 defines a channel region 68 as that portion at the surface of thin silicon layer 38 underlying the gate electrode. Preferably the channel is oriented along a [110] crystal direction so that current flow in the transistor will be in the [110] crystal direction. Further, a cap 69, such as for example a silicon nitride cap is deposited over the oxide layer 64. The method in accordance with one embodiment herein continues by blanket depositing a layer of spacer-forming material 70, such as silicon nitride, overlying cap 69 and liner 64. If of the same material, the cap 69 and spacer-forming material 70 may be considered to be merged as shown in the following Figures. The silicon nitride layer is deposited to a thickness of about 80 to about 250 nm, preferably by LPCVD using dichlorosilane and ammonia as reactants.

As shown in FIG. 4, the spacer-forming material 70 is anisotropically etched to form spacers 71. The etch may be performed anisotropically, for example by reactive ion etching (RIE), using a CF₄ or CHF₃ chemistry, to create spacers 71. Recesses 72 are etched into thin silicon layer 38 using spacers 71, gate electrode 62, and STI 48 as etch masks. Because the spacers 71 are used as an etch mask, the recesses are self aligned to the spacers 71 and are spaced apart from the channel region 68 under the gate electrode by adjacent regions 75 having thicknesses substantially equal to the thickness of the sidewall spacers 71 after etching as indicated by line 76. Recesses 72 are anisotropically etched, for example, by reactive ion etching (RIE) using a HBr/O₂ chemistry to a depth of about 10 to about 20 nm as indicated by line 78. At least a thin portion of silicon layer 38 is left beneath bottom surface 80 of the recesses.

In accordance with an embodiment herein recesses 72 are filled with undoped SiGe 82 by an epitaxial growth process as illustrated in FIG. 5. Then, as shown in FIG. 6, a second layer of spacer-forming material 84, such as for example silicon nitride, is blanket deposited over the cap 69, spacers 71, and SiGe 82. If the second layer of spacer-forming material is the same material as the cap 69 and spacers 71, the layers may be considered to be merged, as shown in FIG. 6. The silicon nitride layer is deposited to a thickness of about 80 to about 250 nm, preferably by LPCVD using dichlorosilane and ammonia as reactants.

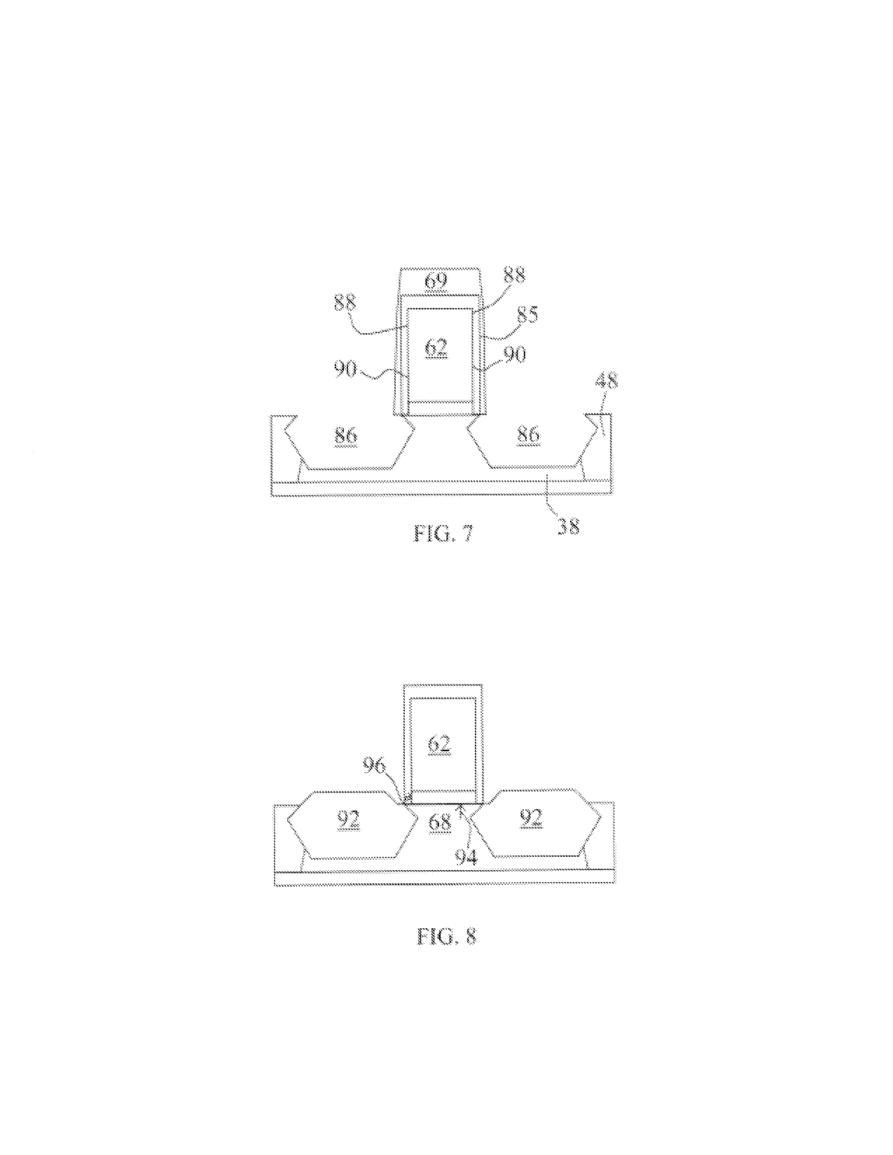

As shown in FIG. 7, the second layer of spacer-forming material 84 can be anisotropically etched to form spacers 85. Then, the spacers 85 are used as an etch mask during an etch, for example a TMAH (tetramethylammonium hydroxide) wet etch process, to create recesses 86. Recesses 86, which are in certain embodiments sigma-shaped, are etched through SiGe 82, and into silicon layer 38 using cap 69, spacers 85, and STI 48 as etch masks. Because the etch rate of the SiGe 82 is about 1.5 times to about 2 times faster than the etch rate of the silicon layer 38 (depending on the Ge content of the SiGe 82), the sigma-shaped recesses 86 extend under the spacers 85 and through the planes 88 formed by the edges or sidewalls 90 of the gate electrode 62. At least a thin portion of silicon layer 38 is left beneath bottom surface of the sigma-shaped recesses.

In accordance with a further embodiment herein the structure illustrated in FIG. 8 is achieved by epitaxially growing in situ boron doped (ISBD) SiGe 92 in the recesses 86 and then removing the spacers 85 from the gate electrode 62. It is noted that due to the non-equilibrium growth conditions of the ISBD-SiGe epitaxy, the boron content in the ISBD-SiGe can be much higher than that provided by ion implantation. Specifically, the boron content may be about 1-5e20 atoms/cm³ (about 0.2 to about 1%). Therefore, the sheet resistance of the source/drain extension areas 92 is reduced (i.e., extrinsic resistance is reduced). Further, as a result of the in situ boron doping process, a much higher germanium content, preferably about 35 to about 40 atomic percent germanium, can be incorporated substitutionally in the SiGe 92, which increases compressive stress on the channel 68 and leads to higher hole mobility in the channel 68 due to reduced intrinsic resistance.

As a result of the processes discussed above, the embedded SiGe 92 forming the source/drain extensions is in closer proximity to the channel 68 in both the vertical direction (arrow 94) and the horizontal direction (arrow 96) than in conventional fabrication methods. Due to the closer proximity of the embedded SiGe 92 to the channel 68, the compressive stress effect on the channel 68 caused by the embedded SiGe 92 is larger, and leads to higher hole mobility in the channel 68 (i.e., intrinsic resistance is further reduced).

Also, due to the epitaxial growth of ISBD-SiGe to form the source/drain extension area 92, the deep source/drain implantations typically used in PMOSFET fabrications can be avoided. As a result, the present fabrication process minimizes the formation of stacking faults as compared to processes using ion implantation. Further, a possible relaxation of the SiGe 92 due to ion implantation is avoided, and a higher compressive stress can be imposed on the channel 68 by the SiGe 92, leading to a higher drive current. In addition, the present process utilizes fewer mask layers than typical fabrication processes, reducing costs. Because of the use of the ISBD-SiGe epitaxial process, conventional rapid thermal annealing (RTA) need not be used in the process herein. Instead, a millisecond ultra fast annealing (UFA) process can be used alone as a final anneal before silicidation to activate the dopants in the extension and deep source/drain areas.

Although not illustrated, the structures illustrated in FIG. 8 can be completed in conventional manner. Conventional steps include, for example, replacing the spacers with a single permanent sidewall spacer. The sidewall spacers can also be used to form self aligned metal silicide contacts to the source and drain regions. A layer of silicide forming metal is deposited and heated to cause the metal to react with exposed silicon or SiGe to form a metal silicide. Metal that is not in contact with exposed silicon such as metal that is deposited on the sidewall spacers or the STI does not react and can be removed by etching in a solution of H₂O₂/H₂SO₄ or HNO₃/HCl. To further stress a MOS transistor a stress liner layer of, for example, stressed silicon nitride may be deposited over the gate electrode and metal silicide contacts. Deposition of the stress liner would be followed by deposition of a dielectric layer, planarization of the dielectric layer, and etching of contact openings through the dielectric layer to the metal silicide contacts. Electrical contact to the source and drain regions can then be made by contact plugs formed in the contact openings and by interconnect metal deposition and patterning.

The foregoing embodiments have been of methods for fabricating stress enhanced PMOS transistors. Similar methods can be used to fabricate stress enhanced NMOS transistors, and the fabrication of either structure or both structures can be integrated into methods for fabricating CMOS integrated circuits including both stressed and unstressed PMOS and NMOS transistors. Fabrication of a stress enhanced NMOS transistor is similar to the methods described above except that the thin silicon layer is impurity doped P-type, the source and drain regions are impurity doped with N-type conductivity determining ions, and the embedded material that is epitaxially grown in the source and drain regions should have a substitutional atom such as carbon such that the grown material has a lattice constant that is smaller than the lattice constant of the host material to create a longitudinal tensional stress on the transistor channel.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration as claimed in any way. Rather, the foregoing detailed description will provide those skilled in the art with a convenient road map for implementing the exemplary embodiment or exemplary embodiments. It should be understood that various changes can be made in the function and arrangement of elements without departing from the scope herein as set forth in the appended claims and the legal equivalents thereof.

What is claimed is:

1. A method for fabricating a stress enhanced MOS device having a channel region at a surface of a semiconductor substrate, the method comprising:
etching first recesses into the semiconductor substrate adjacent the channel region to define adjacent regions in the semiconductor substrate between the first recesses and the channel region;
epitaxially growing a first layer of SiGe in the first recesses;
etching second recesses through the first layer of SiGe and into the adjacent regions in the semiconductor substrate; and
epitaxially growing a second layer of SiGe in the second recesses.

2. The method of claim 1 wherein etching the first recesses is accomplished by a reactive ion etch.

3. The method of claim 1 wherein etching the second recesses is accomplished by a TMAH wet etch.

4. The method of claim 1 wherein etching the second recesses forms sigma-shaped recesses.

5. The method of claim 4 wherein epitaxially growing the first layer of SiGe comprises growing undoped SiGe in the first recesses.

6. The method of claim 1 wherein epitaxially growing the second layer of SiGe comprises growing in situ boron doped SiGe in the second recesses.

7. The method of claim 6 wherein epitaxially growing in situ boron doped SiGe results in the second layer of SiGe comprising about 25 to about 35 atomic percent boron.

8. The method of claim 6 wherein epitaxially growing the second layer of SiGe results in the second layer of SiGe comprising about 35 to about 40 atomic percent germanium.

9. The method of claim 1 further comprising:
depositing a first spacer layer overlying the channel region, wherein etching the first recesses results in first recesses that are self-aligned with the first spacer layer; and
depositing a second spacer layer overlying the channel region and the first layer of SiGe, wherein etching the second recesses results in second recesses that extend under the second spacer layer.

10. The method of claim 1 further comprising:
forming a gate insulator overlying the channel region; and
forming a gate electrode overlying the gate insulator, wherein etching the second recesses comprises etching a portion of the semiconductor substrate under the gate insulator and gate electrode.

11. A method for fabricating a stress enhanced MOS device having a channel region at a surface of a semiconductor substrate beneath a gate electrode, the method comprising:
etching a first recess into the semiconductor substrate adjacent the channel region;
epitaxially growing a first layer of SiGe in the first recess;
etching a second recess through the first layer of SiGe and into the semiconductor substrate beneath the gate electrode; and
epitaxially growing a second layer of SiGe in the second recess.

12. The method of claim 11 wherein the gate electrode is created by forming a gate insulator overlying a semiconductor substrate and by forming the gate electrode overlying the gate insulator, wherein the gate electrode has a side edge defining a plane, and wherein the second recess intersects the plane.

13. The method of claim 11 wherein etching the first recess is accomplished by a reactive ion etch.

14. The method of claim 11 wherein etching the second recess is accomplished by a TMAH wet etch.

15. The method of claim 11 wherein epitaxially growing the first layer of SiGe comprises growing undoped SiGe in the first recess.

16. The method of claim 11 wherein epitaxially growing the second layer of SiGe comprises growing in situ boron doped SiGe in the second recess.

17. The method of claim 16 wherein epitaxially growing in situ boron doped SiGe results in the second layer of SiGe comprising about 25 to about 35 atomic percent boron and about 35 to about 40 atomic percent germanium.

18. The method of claim 11 wherein etching the first recess creates two first recesses surrounding the channel region, wherein the first layer of SiGe is epitaxially grown in the two first recesses, wherein etching the second recess creates two second recesses, and wherein the second layer of SiGe is epitaxially grown in the two second recesses.

19. The method of claim 18 wherein the gate electrode is created by forming a gate insulator overlying a semiconductor substrate and forming the gate electrode overlying the gate insulator, wherein the gate electrode has a first side edge defining a first plane and a second side edge defining a second plane, and wherein the second recesses intersect the first plane and the second plane.

20. A stress enhanced MOS transistor comprising:
a semiconductor substrate having a surface;
a gate electrode formed on the surface;
a channel region at the surface beneath the gate electrode; and
a region of SiGe embedded in the semiconductor substrate adjacent to the channel region and extending beneath the gate electrode.
